(19) United States
(12) Patent Application Publication
(10) Pub. No.: US 2026/0223696 A1
(43) Pub. Date: Jul. 30, 2026

(54) SEMICONDUCTOR PACKAGE

(71) Applicant: SAMSUNG ELECTRONICS CO., LTD., Suwon-si (KR)

(72) Inventors: Taejun JEON, Suwon-si (KR); Wonil SEO, Suwon-si (KR); Yonghyun KIM, Suwon-si (KR); Jeongki JANG, Suwon-si (KR)

(73) Assignee: SAMSUNG ELECTRONICS CO., LTD., Suwon-si (KR)

(21) Appl. No.: 19/352,924

(22) Filed: Oct. 8, 2025

(30) Foreign Application Priority Data
Jan. 24, 2025 (KR) 10-2025-0010907

(51) Int. Cl. H10W 70/60; H10W 70/685; H10W 74/10; H10W 90/00; H10W 46/00; H10W 74/15

(52) U.S. Cl. CPC H10W 70/611; H10W 70/685; H10W 74/117; H10W 90/701; H10W 46/00; H10W 74/15; H10W 90/724; H10W 90/734

(57) ABSTRACT

Provided is a semiconductor package including a substrate having a first surface, a second surface, and a side surface between the first surface and the second surface, the substrate including an insulating layer and a conductive layer in the insulating layer, a plurality of semiconductor chips on the first surface of the substrate and electrically connected to each other through the conductive layer, a mold on the first surface of the substrate, the side surface of the substrate, and at least a portion of each semiconductor chip of the plurality of semiconductor chips, and a connection bump on the second surface of the substrate and electrically connected to the conductive layer, wherein the conductive layer includes a first metal, and wherein an elastic modulus of the conductive layer is smaller than a first elastic modulus of the first metal.

### CROSS-REFERENCE TO RELATED APPLICATION(S

This application claims priority to Korean Patent Application No. 10-2025-0010907 filed on January 24, 2025 in the Korean Intellectual Property Office, the disclosure of which is incorporated herein in its entirety by reference.

### BACKGROUND

Embodiments of the present disclosure relate to a semiconductor package.

Recently, with the increase in wearable devices, flexible devices, or the like, the development of thin and highly flexible semiconductor packages is required. The high elastic modulus of the conductive layer constituting the substrate may be a limitation in securing high flexibility of the semiconductor package.

### SUMMARY

One or more embodiments provide a semiconductor package having improved flexibility.

According to an aspect of one or more embodiments, there is provided a semiconductor package including a substrate having a first surface, a second surface, and a side surface between the first surface and the second surface, the substrate including an insulating layer and a conductive layer in the insulating layer, a plurality of semiconductor chips on the first surface of the substrate and electrically connected to each other through the conductive layer, a mold on the first surface of the substrate, the side surface of the substrate, and at least a portion of each semiconductor chip of the plurality of semiconductor chips, and a connection bump on the second surface of the substrate and electrically connected to the conductive layer, wherein the conductive layer includes a first metal, and wherein an elastic modulus of the conductive layer is smaller than a first elastic modulus of the first metal.

According to another aspect of one or more embodiments, there is provided a semiconductor package including a substrate having a first surface and a second surface opposite to each other, the substrate including an insulating layer and a conductive layer in the insulating layer, a plurality of semiconductor chips on the first surface of the substrate and electrically connected to each other through the conductive layer, and a mold on at least a portion of each of the plurality of semiconductor chips, wherein the conductive layer includes a first conductive portion between adjacent semiconductor chips of the plurality of semiconductor chips, and a second conductive portion connected to the first conductive portion, and wherein an elastic modulus of the first conductive portion is different from an elastic modulus of the second conductive portion.

According to still another aspect of one or more embodiments, there is provided a semiconductor package including a substrate having a first surface, a second surface, and a side surface between the first surface and the second surface, the substrate including an insulating layer and a conductive layer in the insulating layer, a plurality of semiconductor chips on the first surface of the substrate and electrically connected to each other through the conductive layer, and a mold on the first surface of the substrate, the side surface of the substrate, and at least portions of the plurality of semiconductor chips, wherein an elastic modulus of the conductive layer is smaller than or equal to 30 GPa, and wherein an elastic modulus of the insulating layer is smaller than or equal to 20 GPa.

According to further still another aspect of one or more embodiments, there is provided a method of manufacturing a semiconductor package including forming a substrate on a release film using an insulating ink and a conductive ink, the substrate including an insulating layer and a conductive layer in the insulating layer, transferring the substrate onto a carrier, mounting semiconductor chips on the substrate, forming a molding layer on the substrate and the semiconductor chips on the carrier, and cutting the molding layer.

An elastic modulus of the insulating layers may be less than or equal to 20 GPa (25°C), and an elastic modulus of the conductive layer is less than or equal to 30 GPa (25°C).

The conductive ink may include a silver (Ag) or eutectic gallium indium (EGaIn) alloy.

The substrate may include a flexible region having an elastic modulus smaller than an elastic modulus of regions other than the flexible region.

The semiconductor chips may include a first semiconductor chip and a second semiconductor chip, and the flexible region may be between the first semiconductor chip and the second semiconductor chip.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a cross-sectional view of a semiconductor package according to one or more embodiments, and FIG. 1B is a plan view taken along line I-I’ of FIG. 1A;

FIGS. 2A, 2B, and 2C are cross-sectional views of a semiconductor package according to one or more embodiments, respectively;

FIG. 3 is a cross-sectional view of a semiconductor package according to one or more embodiments;

FIG. 4 is a cross-sectional view of a semiconductor package according to one or more embodiments;

FIG. 5 is a cross-sectional view of a semiconductor package according to one or more embodiments;

FIG. 6 is a cross-sectional view of a semiconductor package according to one or more embodiments;

FIG. 7 is a cross-sectional view of a semiconductor package according to one or more embodiments; and

FIGS. 8A, 8B, 8C, 8D, 8E, 8F, 8G, and FIG. 8H are drawings illustrating a method of manufacturing a semiconductor package according to one or more embodiments.

### DETAILED DESCRIPTION

Hereinafter, example embodiments will be described with reference to the attached drawings. Unless otherwise specifically stated, in this specification, terms such as “upper,” “upper surface,” “lower,” “lower surface,” “side surface,” and the like are based on the drawings and may actually vary depending on the direction in which the components are disposed.

In addition, ordinal numbers such as “first,” “second,” “third,” and the like may be used as labels for specific elements, steps, directions, and the like to distinguish various elements, steps, directions, and the like. Terms that are not described using “first,” “second,” or the like in the specification may still be referred to as “first” or “second” in the claims. In addition, terms that are referenced by a specific ordinal number (for example, “first” in a particular claim) may be described elsewhere with a different ordinal number (for example, “second” in the specification or another claim).

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

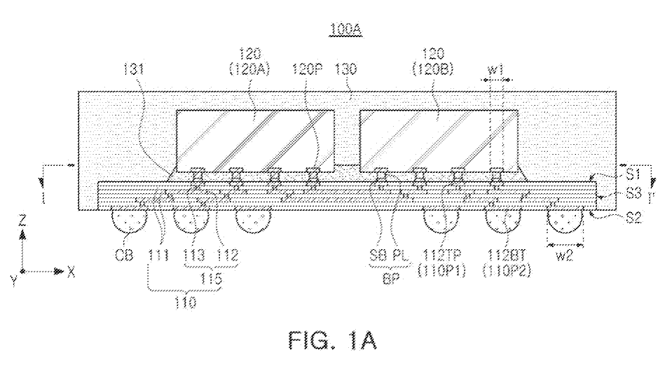

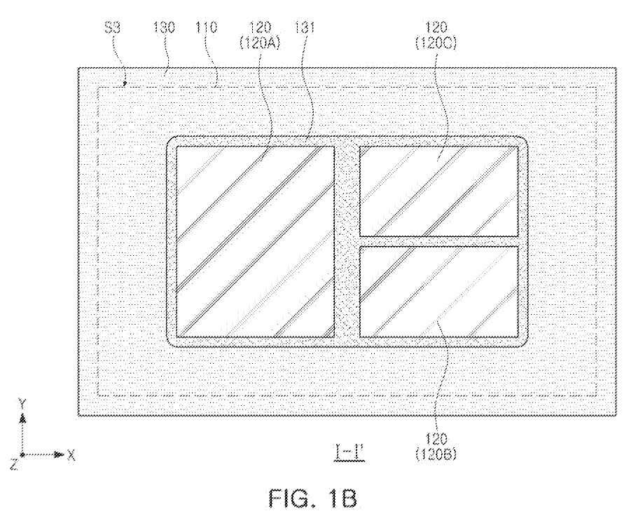

FIG. 1A is a cross-sectional view of a semiconductor package 100A according to one or more embodiments, and FIG. 1B is a plan view taken along line I-I’ of FIG. 1A.

Referring to FIGS. 1A and 1B, the semiconductor package 100A according to one or more embodiments may include a substrate 110 and a plurality of semiconductor chips 120. According to one or more embodiments, the semiconductor package 100A may further include a mold 130 and/or connection bumps CB. The semiconductor package 100A of one or more embodiments includes the substrate 110 made of a material having a relatively low elastic modulus, and thus may have relatively high flexibility suitable for wearable devices, flexible devices, and the like.

The substrate 110 may be a substrate for a semiconductor package on which a plurality of semiconductor chips 120 are mounted. The substrate 110 may have a first surface S1, a second surface S2, and a side surface S3. The first surface S1 may be a surface (for example, upper surface) on which a plurality of semiconductor chips 120 are mounted, and the second surface S2 may be a surface (for example, lower surface) on which connection bumps CB are disposed. The first surface S1 and the second surface S2 may be opposite to each other. The side surface S3 of the substrate 110 is disposed between the first surface S1 and the second surface S2 and may face in a horizontal direction (X- and Y-directions) and extend in a vertical direction (Z direction). The substrate 110 may be electrically connected to an external device, such as a module substrate or a main board, through the connection bumps CB. The connection bumps CB may be disposed on the second surface S2 of the substrate 110 and may be electrically connected to conductive layers 115. The connection bumps CB may include, for example, tin (Sn) or an alloy (for example, Sn-Ag-Cu) including tin (Sn).

The substrate 110 may include two or more insulating layers 111 and two or more conductive layers 115. The conductive layers 115 may include patterns 112 and vias 113 buried in the insulating layers 111. A top pattern 112TP may include first pads 110P1 on which a plurality of semiconductor chips 120 are mounted. A bottom pattern 112BT may include second pads 110P2 on which connection bumps CB are disposed. The insulating layers 111 and the conductive layers 115 may be formed in a number of layers less than or more than that illustrating in the drawing (7 layers). Depending on the process, the boundary between the insulating layers 111 and the boundary between the conductive layers 115 may not be clearly distinguished.

In one or more embodiments, the substrate 110 may be understood as a single substrate in which a package substrate provided for a redistribution function and an interposer substrate provided for a bridge function are merged into one. Accordingly, the gap between the package substrate and the interposer substrate is eliminated, so that the semiconductor package 100A may be made thinner and the manufacturing process thereof may be more simplified. The conductive layers 115 may perform a bridge function for interconnecting a plurality of semiconductor chips 120 and a redistribution function for connecting a plurality of semiconductor chips 120 to connection bumps CB. The conductive layers 115 may be configured to interconnect a plurality of semiconductor chips 120 or connect the same to the connection bumps CB.

The substrate 110 may include first pads 110P1 on a first surface S1 and second pads 110P2 on a second surface S2. The first pads 110P1 may be provided by a top pattern 112TP among the conductive layers 115, and the second pads 110P2 may be provided by a bottom pattern 112BT among the conductive layers 115. In one or more embodiments, the width w2 of the second pads 110P2 may be about 5 times or more the width w1 of the first pads 110P1 in the horizontal direction (X direction and/or Y direction). For example, the width w1 of the first pads 110P1 may be about 10 µm or less, and the width w2 of the second pads 110P2 may be about 50 µm or more. The difference in width between the first pads 110P1 and the second pads 110P2 may be understood as a structure in which a package substrate and an interposer substrate are merged. However, the widths of the first pad 110P1 and the second pad 110P2 are not limited to the above-described values.

In one or more embodiments, the substrate 110 may be composed of a material having a low elastic modulus. For example, the insulating layers 111 may have an elastic modulus of about 20 GPa (25°C) or less, for example, about 0.1 GPa to about 20 GPa, about 1 GPa to about 20 GPa, or about 10 GPa to about 20 GPa, and the conductive layers 115 may have an elastic modulus of about 30 GPa (25°C) or less, for example, about 0.1 GPa to about 30 GPa, about 1 GPa to about 30 GPa, or about 1 GPa to about 10 GPa. The elastic modulus of the insulating layers 111 and the conductive layers 115 may be set to a level required for a specific device to which the semiconductor package 100A is applied.

The insulating layers 111 may be formed by applying an insulating ink. The insulating ink may be applied using a dispenser or a printer. The insulating ink may include a polymer resin synthesized to have an elastic modulus of about 20 GPa or less after curing. For example, the insulating ink may include a synthetic resin of at least one among an epoxy resin, a phenolic resin, a melamine resin, a polyester resin, a silicone resin, a urethane resin, a polyamide resin, and an acrylic resin.

The conductive layers 115 may be formed by applying a conductive ink. The conductive ink may be applied using a dispenser or a printer. The conductive ink may include at least one metal from among copper (Cu), aluminum (Al), nickel (Ni), silver (Ag), gold (Au), platinum (Pt), tin (Sn), lead (Pb), titanium (Ti), chromium CR, palladium (Pd), gallium (Ga), indium (In), and zinc (Zn). The conductive layers 115 may have an elastic modulus lower (smaller) than an elastic modulus of the metal included in the conductive ink. In this case, the elastic modulus of the metal may be an elastic modulus of a pure metal or an elastic modulus of a metal formed by a plating process. In addition, pure metal may indicate having chemical purity (for example, about 99.99% or more).

As an example, the conductive layers 115 include a first metal (for example, silver), and the elastic modulus of the conductive layers 115 may be lower than the first elastic modulus of the first metal (for example, silver). The first elastic modulus of the first metal (for example, silver) may be understood as the elastic modulus of the pure first metal (for example, silver) (about 80 GPa, 25°C) or the elastic modulus of the plated first metal (for example, silver) (about 80 GPa or less, 25°C). The conductive layers 115 may have a porous structure and may have an elastic modulus of about 25 GPa (25°C) or less.

As an example, the conductive layers 115 include a first metal (for example, gallium) and a second metal (for example, indium), and an elastic modulus of the conductive layers 115 may be lower than a first elastic modulus of the first metal (for example, gallium) and a second elastic modulus of the second metal (for example, indium). The first elastic modulus of the first metal (for example, gallium) may be understood as an elastic modulus of the pure first metal (for example, gallium) (about 9.8 GPa, 25°C) or an elastic modulus of the plated first metal (for example, gallium) (about 9.8 GPa or less, 25°C). The second elastic modulus of the second metal (for example, indium) may be understood as the elastic modulus of the pure second metal (for example, indium) (about 11 GPa, 25°C) or the elastic modulus of the plated second metal (for example, indium) (about 11 GPa or less, 25°C). The conductive layers 115 may include a eutectic gallium indium (EGaIn) alloy. The conductive layers 115 may include a ductile portion and a thin film portion covering a surface of the ductile portion. The ductile portion may include an alloy (78.6 wt% Ga, 21.4 wt% In) of the first metal (for example, gallium) and the second metal (for example, indium). The thin film portion may include an oxide (for example, Ga₂O₃ of the first metal (for example, gallium). The conductive layers 115 (in detail, the ductile portion) may have an elastic modulus of about 4 MPa (25°C) or less.

A plurality of semiconductor chips 120 may be disposed on the first surface S1 of the substrate 110 and may be electrically connected to each other through the conductive layers 115. The plurality of semiconductor chips 120 may be disposed to be spaced apart from each other in the horizontal direction (X direction or Y direction). The plurality of semiconductor chips 120 may be electrically connected to each other through the conductive layers 115 of the substrate 110. The plurality of semiconductor chips 120 may include fewer or more semiconductor chips than those illustrating in the drawing. The plurality of semiconductor chips 120 may each include a connection pad 120P. The connection pad 120P may include one of copper (Cu), nickel (Ni), titanium (Ti), aluminum (Al), or alloys thereof. The connection pad 120P may be electrically connected to the first pad 110P1 via a micro bump BP. The micro bump BP may include a pillar portion PL and a solder portion SB. The pillar portion PL may include copper (Cu) or an alloy of copper (Cu), and the solder portion SB may include a relatively low-melting-point metal, for example, tin (Sn) or an alloy (for example, Sn-Ag) including tin (Sn).

The plurality of semiconductor chips 120 may include logic chips (or processor chips) such as a central processor (CPU), a graphic processor (GPU), a field programmable gate array (FPGA), an application processor (AP), a digital signal processor, an encryption processor, a microprocessor, a microcontroller, an analog-to-digital converter, an application-specific IC (ASIC), an application processor (AP), and a memory chip including volatile memory such as dynamic RAM (DRAM), static RAM (SRAM), and nonvolatile memory such as phase change RAM (PRAM), magnetic RAM (MRAM), resistive RAM (RRAM), and flash memory. For example, the plurality of semiconductor chips 120 may include a first semiconductor chip 120A, a second semiconductor chip 120B, and a third semiconductor chip 120C. According to one or more embodiments, at least some of the first semiconductor chip 120A, the second semiconductor chip 120B, and the third semiconductor chip 120C may include different types of semiconductor chips. For example, the first semiconductor chip 120A may include a logic chip such as a CPU, a GPU, an ASIC, and the like, and the second and third semiconductor chips 120B and 120C may include a memory chip such as a DRAM, a flash memory, and the like. According to one or more embodiments, the second and third semiconductor chips 120B and 120C may be provided as a high-performance memory device such as an high bandwidth memory (HBM), a hybrid memory cube (HMC), or the like.

The mold 130 may encapsulate at least portions of the plurality of respective semiconductor chips 120. The mold 130 may include a thermosetting resin such as an epoxy resin, a thermoplastic resin such as a polyimide, or a resin impregnated with an inorganic filler in the resin, for example, prepreg, Ajinomoto Build-up Film (ABF), FR-4 (Flame Retardant), Bismaleimide Triazine (BT), or epoxy molding compound (EMC). The mold 130 may be provided on and/or cover the first surface S1 and the side surface S3 of the substrate 110. The mold 130 may be provided based on a manufacturing process of the substrate 110 using a release film. In addition, in one or more embodiments, the mold 130 may have an elastic modulus of about 20 GPa or less. The elastic modulus of the mold 130 may be set to a level required for a specific device to which the semiconductor package 100A is applied. For example, the elastic modulus of the mold 130 may be controlled by the content of a filler (for example, silica). According to one or more embodiments, an underfill 131 may be disposed between a plurality of semiconductor chips 120 and a substrate 110. The underfill 131 may have a capillary underfill (CUF) structure, but is not limited thereto. In one or more embodiments, the underfill 131 may have a molded underfill (MUF) structure that is integrated with the mold 130.

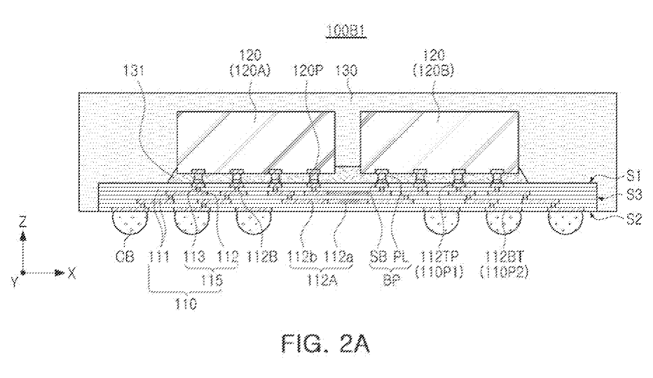

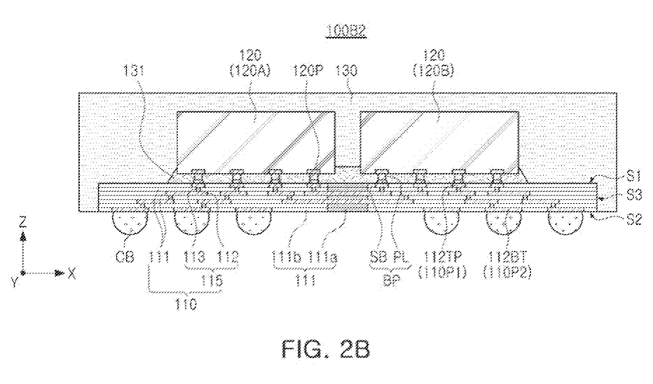

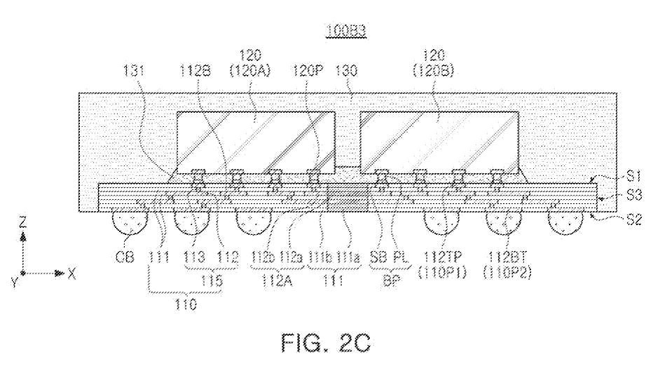

FIG. 2A to 2C are cross-sectional views of semiconductor packages according to example embodiments, respectively. FIG. 2A to 2C illustrate embodiments in which the substrate 110 partially includes a region having a lower elastic modulus.

Referring to FIG. 2A, a semiconductor package 100B1 of one or more embodiments may include features identical to or similar to those described with reference to FIGS. 1A and 1B, except that it includes a first conductive portion 112a and a second conductive portion 112b having different elastic modulus. The conductive layers 115 may include a first conductive layer 112A connecting a plurality of semiconductor chips 120 to each other, and a second conductive layer 112B connecting the plurality of semiconductor chips 120 and the connection bumps CB. The first conductive layer 112A may include the first conductive portion 112a and the second conductive portion 112b. The first conductive portion 112a may be positioned between the plurality of semiconductor chips 120. The first conductive portion 112a may overlap at least a space between the plurality of semiconductor chips 120 in a vertical direction (Z direction). The second conductive portion 112b may be connected to at least one side of the first conductive portion 112a. The second conductive portion 112b may extend from both sides of the first conductive portion 112a and may be connected to a plurality of semiconductor chips 120, respectively. The first conductive portion 112a and the second conductive portion 112b may be composed of different materials. The elastic modulus of the first conductive portion 112a may be lower than the elastic modulus of the second conductive portion 112b. The second conductive layer 112B may include a material that is the same as or similar to a material of the second conductive portion 112b. The elastic modulus of the second conductive layer 112B may be larger than the elastic modulus of the first conductive portion 112a.

As an example, the first conductive portion 112a may include a first metal (for example, silver). The elastic modulus of the first conductive portion 112a may be less than the elastic modulus of the pure first metal (for example, silver) (about 80 GPa, 25°C) or the elastic modulus of the plated first metal (for example, silver) (about 80 GPa or less, 25°C). The second conductive portion 112b may include a second metal (for example, copper) different from the first metal (for example, silver). The elastic modulus of the second conductive portion 112b may be less than the elastic modulus of the pure second metal (for example, copper) or the elastic modulus of the plated second metal (for example, copper).

As an example, the first conductive portion 112a may include a eutectic gallium indium (EGaIn) alloy. The first conductive portion 112a may include a first metal (for example, gallium) and a second metal (for example, indium). The elastic modulus of the first conductive portion 112a may be lower than the elastic modulus of the pure first metal (for example, gallium) or the elastic modulus of the plated first metal (for example, gallium). Additionally, the elastic modulus of the first conductive portion 112a may be lower than the elastic modulus of the pure second metal (for example, indium) or the elastic modulus of the plated second metal (for example, indium). The second conductive portion 112b may include a third metal (for example, copper).

Referring to FIG. 2B, a semiconductor package 100B2 of one or more embodiments may include the same or similar features as described with reference to FIGS. 1A and 1B, except that it includes a first insulating portion 111a and a second insulating portion 111b having different elastic modulus. The insulating layers 111 may include a first insulating portion 111a and a second insulating portion 111b. The first insulating portion 111a may be positioned between a plurality of semiconductor chips 120 in the horizontal direction (X direction and/or Y direction). The first insulating portion 111a may overlap at least a space between the plurality of semiconductor chips 120 in the vertical direction (Z direction). In addition, the first insulating portion 111a may overlap a portion of the plurality of semiconductor chips 120 in the vertical direction (Z direction). In some embodiments, the first insulating portion 111a may not overlap a portion of the plurality of semiconductor chips 120 in the vertical direction (Z direction). The second insulating portion 111b may be connected to at least one side of the first insulating portion 111a. The second insulating portion 111b may extend from both sides of the first insulating portion 111a. The first insulating portion 111a and the second insulating portion 111b may be composed of different materials. The elastic modulus of the first insulating portion 111a may be lower than the elastic modulus of the second insulating portion 111b.

As an example, the first insulating portion 111a may include a polymer resin synthesized to have an elastic modulus of about 20 GPa or less. The second insulating portion 111b may include a polymer resin synthesized to have an elastic modulus greater than the elastic modulus of the first insulating portion 111a. The first insulating portion 111a and the second insulating portion 111b may include at least one synthetic resin among an epoxy resin, a phenolic resin, a melamine resin, a polyester resin, a silicone resin, a urethane resin, a polyamide resin, and an acrylic resin.

Referring to 2C, a semiconductor package 100B3 of one or more embodiments may include features identical or similar to those described with reference to FIGS. 1A and 1B, except that it includes both the first insulating portion 111a and the second insulating portion 111b, and the first conductive portion 112a and the second conductive portion 112b.

In an example, the first conductive portion 112a may include a first metal (for example, silver). The elastic modulus of the first conductive portion 112a may be less than the elastic modulus of the pure first metal (for example, silver) (about 80 GPa, 25°C) or the elastic modulus of the plated first metal (for example, silver) (about 80 GPa or less, 25°C). The second conductive portion 112b may include a second metal (for example, copper) different from the first metal (for example, silver). The elastic modulus of the second conductive portion 112b may be lower than the elastic modulus of the pure second metal (for example, copper) or the elastic modulus of the plated second metal (for example, copper).

As an example, the first conductive portion 112a may include a eutectic gallium indium (EGaIn) alloy. The first conductive portion 112a may include the first metal (for example, gallium) and the second metal (for example, indium). The elastic modulus of the first conductive portion 112a may be lower than the elastic modulus of the pure first metal (for example, gallium) or the elastic modulus of the plated first metal (for example, gallium). Additionally, the elastic modulus of the first conductive portion 112a may be lower than the elastic modulus of the pure second metal (for example, indium) or the elastic modulus of the plated second metal (for example, indium). The second conductive portion 112b may include a third metal (for example, copper).

As an example, the first insulating portion 111a may include a polymer resin synthesized to have an elastic modulus of about 20 GPa or less. The second insulating portion 111b may include a polymer resin synthesized to have an elastic modulus greater than the elastic modulus of the first insulating portion 111a. The first insulating portion 111a and the second insulating portion 111b may include a synthetic resin of at least one among an epoxy resin, a phenolic resin, a melamine resin, a polyester resin, a silicone resin, a urethane resin, a polyamide resin, and an acrylic resin.

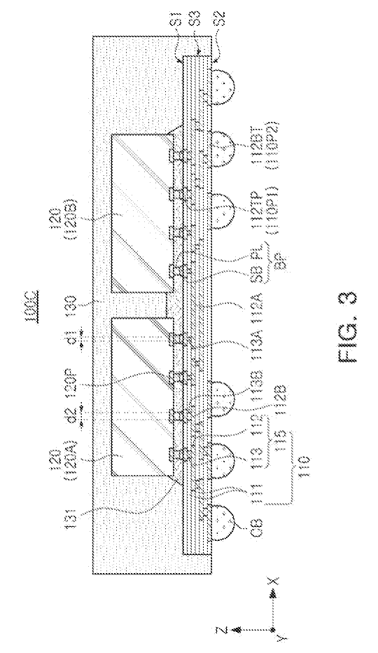

FIG. 3 is a cross-sectional view of a semiconductor package 100C according to one or more embodiments.

Referring to FIG. 3, a semiconductor package 100C of one or more embodiments may have the same or similar features as those described with reference to FIGS. 1A to 2C, except that it includes vias 113 with different diameters. The conductive layers 115 may include a first via 113A connecting a plurality of semiconductor chips 120 to each other, and a second via 113B connecting the plurality of semiconductor chips 120 and connection bumps CB. The first via 113A may connect the first conductive layers 112A in the vertical direction (Z direction). The second via 113B may connect the second conductive layers 112B in the vertical direction (Z direction). To reduce process difficulty and improve connection reliability of the conductive layers 115, the first via 113A may be formed at a fine pitch compared to the second via 113B. For example, the diameter d1 of the first via 113A may be smaller than the diameter d2 of the second via 113B.

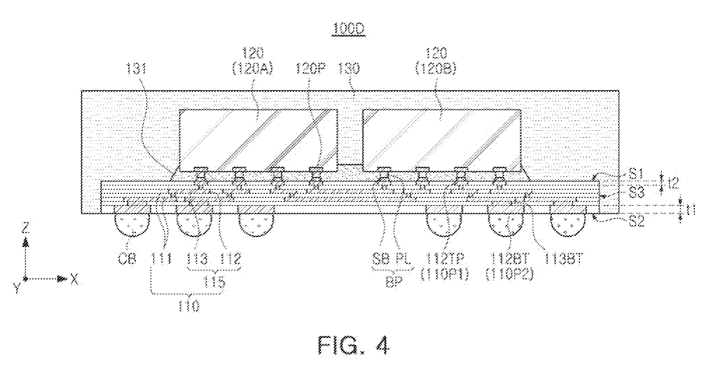

FIG. 4 is a cross-sectional view of a semiconductor package 100D according to one or more embodiments.

Referring to FIG. 4, the semiconductor package 100D of one or more embodiments may have the same or similar features as those described with reference to FIGS. 1A to 3, except that it includes patterns 112 with different thicknesses. To reduce process difficulty and improve connection reliability of conductive layers 115, relatively thick patterns 112 may be formed in areas with high design freedom, areas where fine pitch is not required, or the like. The conductive layers 115 may include a top pattern 112TP adjacent to a first surface S1, and a bottom pattern 112BT adjacent to a second surface S2. The top pattern 112TP may provide a first pad 110P1 to which a micro bump BP is attached. The bottom pattern 112BT may provide a second pad 110P2 to which a connection bump CB is attached. For example, the thickness t1 of the bottom pattern 112BT may be greater than the thickness t2 of the top pattern 112TP. According to one or more embodiments, the bottom via 113BT in contact with the bottom pattern 112BT may have a larger diameter than diameters of the other vias 113.

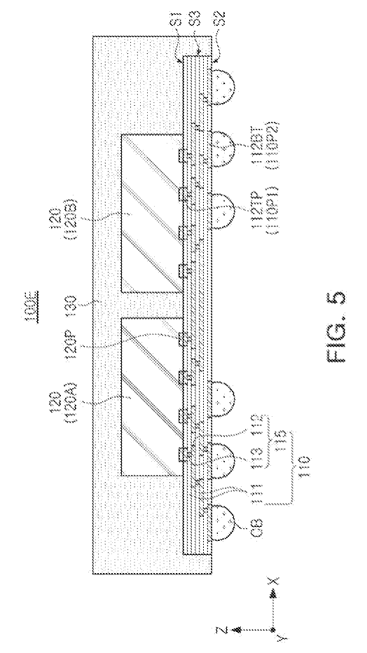

FIG. 5 is a cross-sectional view of a semiconductor package 100E according to one or more embodiments.

Referring to FIG. 5, the semiconductor package 100E of one or more embodiments may have the same or similar features as those described with reference to FIGS. 1A to 4, except that the plurality of semiconductor chips 120 are directly bonded and connected to the substrate 110 without a separate conductive member (for example, micro bump). The connection pads 120P of the plurality of semiconductor chips 120 may be directly bonded and connected to the first pad 110P1 of the substrate 110 by metal-to-metal bonding. The connection pad 120P may be a chip pad of a bare die or a conductive structure on the chip pad. The connection pad 120P may include at least one of a material capable of forming a metal-to-metal bond, for example, copper (Cu), nickel (Ni), gold (Au), silver (Ag), titanium (Ti), and tantalum (Ta).

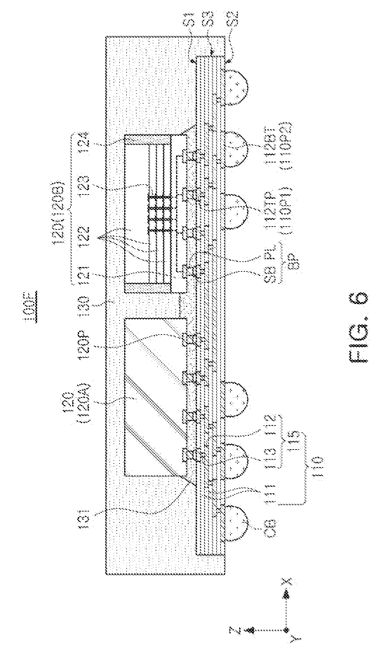

FIG. 6 is a cross-sectional view of a semiconductor package 100F according to one or more embodiments.

Referring to FIG. 6, the semiconductor package 100F according to one or more embodiments may have the same or similar features as those described with reference to FIGS. 1A to 5, except that at least one semiconductor chip 120B is provided as a high-capacity memory device. For example, the first semiconductor chip 120A may be a logic chip including an ASIC and the like, and the second semiconductor chip 120B may be a high-capacity memory device including memory dies 122. The second semiconductor chip 120B may include a base die 121, a memory die 122, and an encapsulant 124.

The base die 121 may be a buffer chip or a control chip including a plurality of logic elements and/or memory elements. The base die 121 may include a buffer circuit or a control circuit that transmits signals from the memory dies 122 to the outside, and also transmits signals and power from the outside to the memory dies 122.

The memory die 122 may be a memory chip including volatile memory elements such as DRAM and SRAM, or nonvolatile memory elements such as PRAM, MRAM, FeRAM, RRAM, and flash memory. The memory dies 122 may be electrically connected to each other through a through-electrode 123. In one or more embodiments, the memory die 122 positioned at the top does not include a through-electrode 123 and may have a relatively large thickness.

The encapsulant 124 is disposed on the base die 121 and may encapsulate at least portions of the respective memory dies 122, and be provided on side surfaces of the memory dies. The encapsulant 124 may be formed to expose the upper surface of the uppermost memory die 122. The encapsulant 124 may be formed using, for example, EMC.

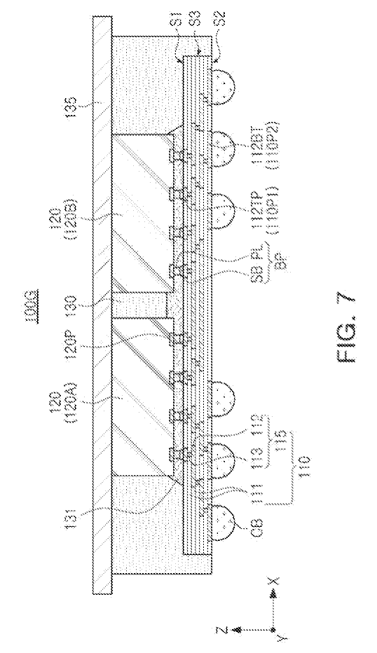

FIG. 7 is a cross-sectional view of a semiconductor package 100G according to one or more embodiments.

Referring to FIG. 7, the semiconductor package 100G according to one or more embodiments may have the same or similar features as those described with reference to FIGS. 1A to 6, except that it further includes a heat dissipation structure 135. The heat dissipation structure 135 may be formed on and/or to cover the upper portions of the plurality of semiconductor chips 120. The heat dissipation structure 135 may be attached to the mold 130 by an adhesive. The adhesive may be a thermally conductive adhesive tape, a thermally conductive grease, a thermally conductive adhesive, or the like. According to one or more embodiments, the heat dissipation structure 135 may be in contact with the upper surfaces of the plurality of semiconductor chips 120. A layer of thermal interface material may be disposed between the heat dissipation structure 135 and the plurality of semiconductor chips 120. The heat dissipation structure 135 may include a material having excellent thermal conductivity, for example, a metal or metal alloy including gold (Au), silver (Ag), copper (Cu), iron (Fe), or a material such as graphite, graphene, or the like. The heat dissipation structure 135 may have a shape different from that illustrating in the drawing. For example, the heat dissipation structure 135 may have a cap shape that extends to the side surface of the mold 130.

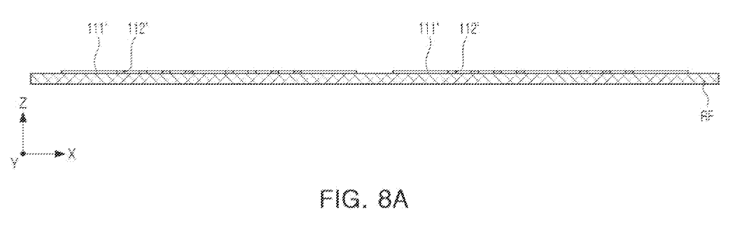

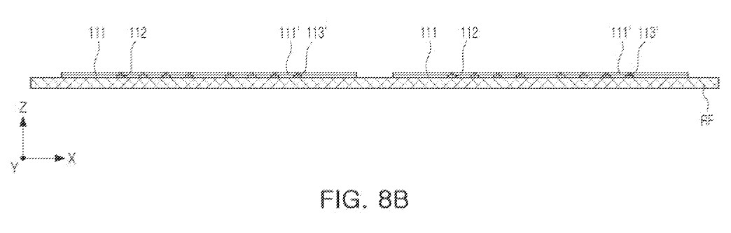

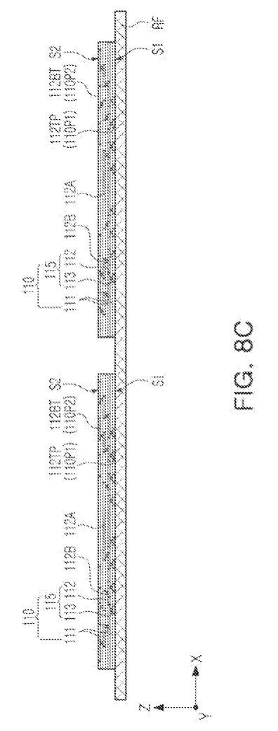

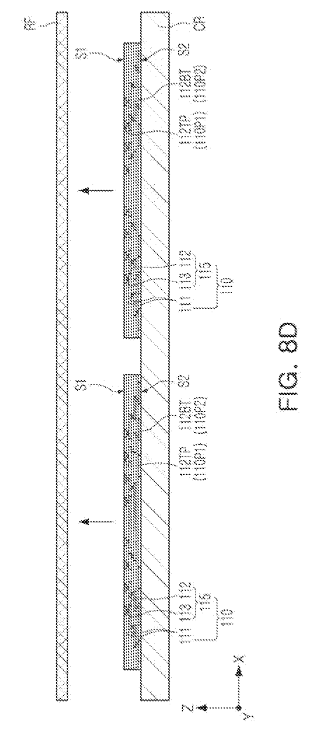

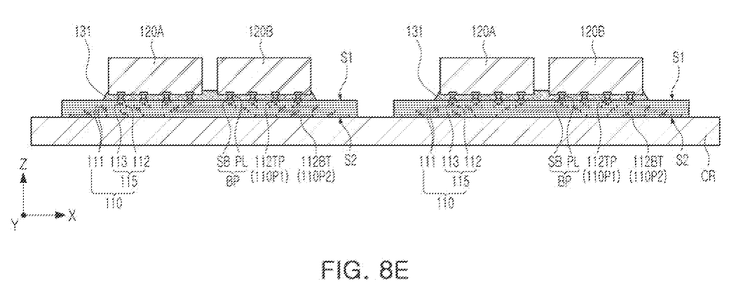

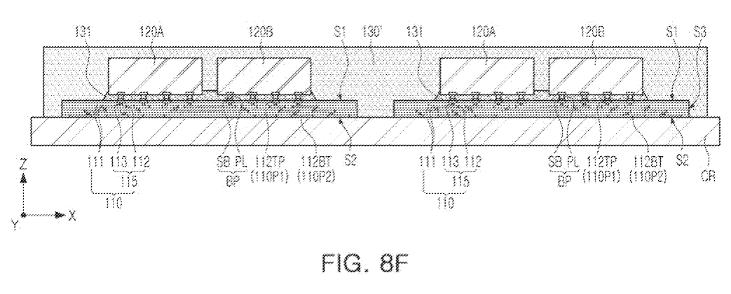

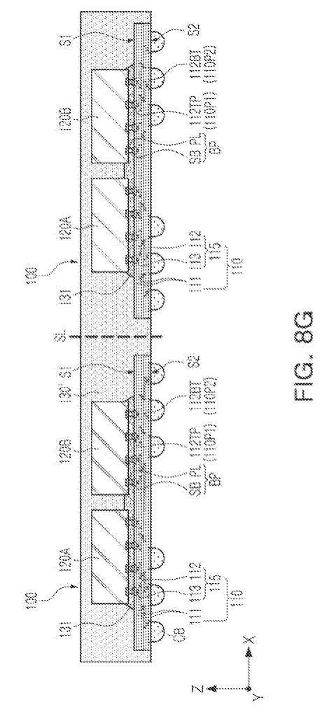

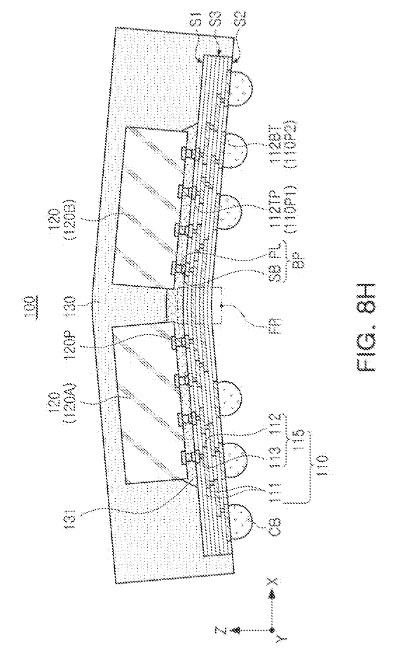

FIGS. 8A to 8H are drawings illustrating a method of manufacturing a semiconductor package according to one or more embodiments.

Referring to FIG. 8A, an insulating material layer 111’ and a pattern layer 112’ may be formed on a release film RF. The release film RF may include a photocurable film, a thermocurable film, or the like. The insulating material layer 111’ may be formed by applying an insulating ink including, for example, an epoxy resin. The insulating ink may be applied onto the release film RF using a dispenser or a printer. The insulating material layer 111’ may be formed around the pattern layer 112’. The insulating material layer 111’ may be formed to have substantially the same thickness as the pattern layer 112’ in the vertical direction (Z direction). The pattern layer 112’ may be formed by applying a conductive ink including, for example, silver (Ag) or a eutectic gallium indium (EGaIn) alloy. The conductive ink may be applied onto the release film RF using a dispenser or a printer. The pattern layer 112’ may be formed according to a pattern of the mask. Thereafter, the insulating material layer 111’ may be cured, and the pattern layer 112’ may be cured or oxidized.

Referring to FIG. 8B, an insulating material layer 111’ and a via layer 113’ may be formed on the insulating layer 111 and the pattern 112. The insulating layer 111 may be formed by curing the applied insulating material layer 111’. The pattern 112 may be formed by curing or oxidizing the applied pattern layer 112’. The via layer 113’ may be formed by applying a conductive ink including, for example, silver (Ag) or a eutectic gallium indium (EGaIn) alloy. The conductive ink may be applied on the release film RF using a dispenser or a printer. The via layer 113’ may be formed according to a designed pattern of the mask.

Referring to FIG. 8C, a substrate 110 may be formed by repeating the process of forming insulating layers 111, patterns 112, and vias 113. The substrate 110 may have a first surface S1 attached to a release film RF and a second surface S2 opposite to the first surface S1. The substrate 110 may include conductive layers 115 composed of patterns 112 and vias 113. The insulating layers 111 may have an elastic modulus of about 20 GPa (25°C) or less, and the conductive layers 115 may have an elastic modulus of about 30 GPa (25°C) or less. The conductive layers 115 may have a porous structure or a structure in which a metal oxide film is formed on a surface. According to one or more embodiments, the insulating layers 111 and/or the conductive layers 115 may include portions formed of different types of ink. The insulating layers 111 may include a first insulating portion 111a formed of a first insulating ink and a second insulating portion 111b formed of a second insulating ink. The first insulating ink may include a synthetic resin having an elastic modulus lower than an elastic modulus of the second insulating ink (see FIGS. 2B and 2C). The first conductive layer 112A may include a first conductive portion 112a formed of a first conductive ink and a second conductive portion 112b formed of a second conductive ink. The first conductive ink may include a metal (or alloy) having an elastic modulus lower than the elastic modulus of the second conductive ink (see FIG. 2A and 2C).

Referring to FIG. 8D, the release film RF may be removed to expose the first surface S1 of the substrate 110, and a carrier CR may be attached to the second surface S2 of the substrate 110. The substrates 110 may be transferred onto the carrier CR. The carrier CR may include a release layer for separating the substrates 110. After the release film RF is removed, the first pads 110P1 of the substrate 110 may be exposed upward.

Referring to FIG. 8E, semiconductor chips 120A, 120B may be disposed on a substrate 110. The semiconductor chips 120A, 120B may be mounted in a flip-chip manner. The semiconductor chips 120A, 120B may be connected to the first pad 110P1 through a micro bump BP. According to one or more embodiments, an underfill 131 surrounding the micro bump BP may be formed.

Referring to FIG. 8F, a molding layer 130’ may be formed. The molding layer 130’ may be formed on and/or to cover the substrates 110 and the semiconductor chips 120A, 120B on the carrier CR. The molding layer 130’ may be formed by applying and curing a molding material such as EMC. The molding layer 130’ may cover the side surface S3 of the substrates 110 transferred from the release film RF.

Referring to FIGS. 8G and 8H, the semiconductor packages 100 may be separated by cutting the molding layer 130’ along the scribe lane SL. The semiconductor package 100 includes a substrate 110 made of a material having a relatively low elastic modulus, and thus may have improved flexibility suitable for wearable devices, flexible devices, and the like. According to one or more embodiments, the semiconductor package 100 may include a substrate 110 on which a flexible region FR is formed. The flexible region FR may be located between the first semiconductor chip 120A and the second semiconductor chip 120B. Therefore, the semiconductor package 100 may have improved flexibility required for wearable devices, flexible devices, or the like. In one or more embodiments, the flexible region FR may be a region having a lower elastic modulus compared to elastic modulus of other portions of the substrate 110 (see FIGS. 2A to 2C for examples).

As set forth above, according to one or more embodiments, by introducing a substrate composed of a material having a relatively low elastic modulus, a semiconductor package having improved flexibility and a method of manufacturing the same may be provided.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a substrate having a first surface, a second surface, and a side surface between the first surface and the second surface, the substrate comprising an insulating layer and a conductive layer in the insulating layer;
a plurality of semiconductor chips on the first surface of the substrate and electrically connected to each other through the conductive layer;
a mold on the first surface of the substrate, the side surface of the substrate, and at least a portion of each semiconductor chip of the plurality of semiconductor chips; and
a connection bump on the second surface of the substrate and electrically connected to the conductive layer,
wherein the conductive layer comprises a first metal, and
wherein an elastic modulus of the conductive layer is smaller than a first elastic modulus of the first metal.

2. The semiconductor package of claim 1, wherein the first elastic modulus of the first metal is an elastic modulus of a pure first metal or an elastic modulus of a plated first metal.

3. The semiconductor package of claim 2, wherein the first metal comprises at least one of copper (Cu), aluminum (Al), nickel (Ni), silver (Ag), gold (Au), platinum (Pt), tin (Sn), lead (Pb), titanium (Ti), chromium (Cr), palladium (Pd), gallium (Ga), indium (In), and zinc (Zn).

4. The semiconductor package of claim 1, wherein the conductive layer has a porous structure.

5. The semiconductor package of claim 1, wherein the conductive layer further comprises a second metal, and
wherein an elastic modulus of the conductive layer is smaller than a second elastic modulus of the second metal.

6. The semiconductor package of claim 5, wherein the first elastic modulus of the first metal is an elastic modulus of a pure first metal or an elastic modulus of a plated first metal, and
wherein the second elastic modulus is an elastic modulus of a pure second metal or an elastic modulus of a plated second metal.

7. The semiconductor package of claim 6, wherein the first metal comprises gallium (Ga), and
wherein the second metal comprises indium (In).

8. The semiconductor package of claim 5, wherein the conductive layer comprises a ductile portion and a thin film portion on the ductile portion, and
wherein the ductile portion comprises an alloy of the first metal and the second metal, and
wherein the thin film portion comprises an oxide of the first metal.

9. The semiconductor package of claim 8, wherein the ductile portion comprises a eutectic gallium indium (EGaIn) alloy.

10. The semiconductor package of claim 1, wherein an elastic modulus of the insulating layer is smaller than or equal to 20 GPa.

11. The semiconductor package of claim 10, wherein the insulating layer comprises a synthetic resin of at least one of epoxy resin, phenolic resin, melamine resin, polyester resin, silicone resin, urethane resin, polyamide resin, and acrylic resin.

12. The semiconductor package of claim 1, wherein an elastic modulus of the mold is smaller than or equal to 20 GPa.

13. The semiconductor package of claim 1, wherein the conductive layer comprises a first conductive layer connecting the plurality of semiconductor chips to each other, and a second conductive layer connecting the plurality of semiconductor chips and the connection bump,
wherein the first conductive layer comprises a first conductive portion between the plurality of semiconductor chips, and a second conductive portion connected to at least one side of the first conductive portion, and
wherein an elastic modulus of the first conductive portion is smaller than an elastic modulus of the second conductive portion.

14. The semiconductor package of claim 1, wherein the insulating layer comprises a first insulating portion between adjacent semiconductor chips of the plurality of semiconductor chips, and a second insulating portion connected to at least one side of the first insulating portion, and
wherein an elastic modulus of the first insulating portion is smaller than an elastic modulus of the second insulating portion.

15. The semiconductor package of claim 1, further comprising a first pads between the substrate and the plurality of semiconductor chips, and a second pad between the substrate and the connection bump,
wherein a width of the second pad is greater than or equal to 5 times of a width of the first pads.

16. A semiconductor package comprising:
a substrate having a first surface and a second surface opposite to each other, the substrate comprising an insulating layer and a conductive layer in the insulating layer;
a plurality of semiconductor chips on the first surface of the substrate and electrically connected to each other through the conductive layer; and
a mold on at least a portion of each of the plurality of semiconductor chips,
wherein the conductive layer comprises a first conductive portion between adjacent semiconductor chips of the plurality of semiconductor chips, and a second conductive portion connected to the first conductive portion, and
wherein an elastic modulus of the first conductive portion is different from an elastic modulus of the second conductive portion.

17. The semiconductor package of claim 16, wherein the elastic modulus of the first conductive portion is smaller than the elastic modulus of the second conductive portion.

18. The semiconductor package of claim 16, wherein the insulating layer comprises a first insulating portion between adjacent semiconductor chips of the plurality of semiconductor chips, and a second insulating portion connected to the first insulating portion, and
wherein an elastic modulus of the first insulating portion is different from an elastic modulus of the second insulating portion.

19. The semiconductor package of claim 18, wherein the elastic modulus of the first insulating portion is smaller than the elastic modulus of the second insulating portion.

20. A semiconductor package comprising:
a substrate having a first surface, a second surface, and a side surface between the first surface and the second surface, the substrate comprising an insulating layer and a conductive layer in the insulating layer;
a plurality of semiconductor chips on the first surface of the substrate and electrically connected to each other through the conductive layer; and
a mold on the first surface of the substrate, the side surface of the substrate, and at least portions of the plurality of semiconductor chips,
wherein an elastic modulus of the conductive layer is smaller than or equal to 30 GPa, and
wherein an elastic modulus of the insulating layer is smaller than or equal to 20 GPa.
